(19) United States
(12) Patent Application Publication
(10) Pub. No.: US 2007/0105360 A1
(43) Pub. Date: May 10, 2007

(54) Method of Forming Bump, Method of Forming Image Sensor Using the Method, Semiconductor Chip and the Sensor so Formed

(76) Inventor: Jong-Wook Hong, Seoul (KR)

Correspondence Address: Frank Chau, Esq.;F. CHAU & ASSOCIATES, LLC, 130 Woodbury Road, Woodbury, NY, 11797, US

(21) Appl. No.: 11/557,753

(22) Filed: Nov. 8, 2006

(30) Foreign Application Priority Data
Nov. 8, 2005 (KR) 2005-106596

(51) Int. Cl. H01L 21/44; H01L 23/48

(52) U.S. Cl. 438/612; 257/780

(57) ABSTRACT

A method of forming a bump, a method of forming an image sensor using the method, a semiconductor chip and the sensor so formed. According to a method of forming the bump, a conductive pad is used as a seed layer to form the bump by a plating process. Since the conductive pad is used as a seed layer, it is not necessary to form an additional aluminum pad or seed layer and the manufacturing process is simplified. The conductive pad and the bump are formed of the same materials simplifying the manufacturing a process.

### CROSS-REFERENCE TO RELATED APPLICATIONS

This application claims priority under 35 U.S.C § 119 to Korean Patent Application No. 2005-106596, filed on Nov. 8, 2005, the entire contents of which are hereby incorporated by reference.

### BACKGROUND OF THE INVENTION

1. Technical Field

The present invention relates to a semiconductor device, more particularly, a method of forming a bump, a method of forming an image sensor using the method, a semiconductor chip and a sensor so formed.

2. Discussion of the Related Art

Semiconductors are generally packaged for mounting within electronic devices. There is a trend for using packaging that is light, thin, short and narrow. A semiconductor chip and a circuit substrate may be connected by using a bump to minimize a mounting area. A packaging method using a bump may reduce inductance, capacitance and signal delay by keeping a short electric connection length. Use of bumps may allow for input-output of multi-pins and desirable thermal properties. By applying a bump to an image sensor, an area of a light receiving part is extended by the length of the bump.

The bump may be formed of gold having a low electric resistance. However, gold is expensive. Accordingly, a bump may be formed of relatively cheap copper having a high electric resistance compared with gold. In addition to the bump, a wire in a semiconductor device is formed of copper for the same reason. However, since the use of copper may readily pollute semiconductor manufacturing lines, great caution is needed.

When a pattern is formed of copper or gold, it may be difficult to use a damascene process. For example, when using the damascene process, a conductive pad located on the top of a semiconductor formed of copper may have an upper surface that is as high as an upper surface of a neighboring interlayer dielectric layer. Accordingly, a conductive pad formed of copper is located in an interlayer dielectric layer. It may therefore be difficult to form a bump to connect to the conductive pad. In order to solve this, an aluminum layer is deposited on a wafer where the copper conductive pad is formed and is patterned to form an aluminum pad having a more projected upper surface than an upper surface of the interlayer dielectric layer.

On the other hand, when a bump is formed of gold or copper on the aluminum pad using a plating method, since the aluminum is a different material from the gold or copper, a separate seed layer must be formed of gold or copper thereby complicating the manufacturing process.

### SUMMARY OF THE INVENTION

Exemplary embodiments of the present invention are directed to a method of forming a bump, a method of forming an image sensor using the method, a semiconductor chip and the sensor so formed. In an exemplary embodiment, a method of forming a bump comprises forming a conductive pad on a semiconductor substrate. A passivation layer covering the conductive pad is formed. An opening exposing the conductive pad is formed by patterning the passivation layer. A bump connected to the conductive pad is formed, wherein forming the bump is performed by a plating process using the conductive pad as a seed layer.

In another exemplary embodiment, a method of forming an image sensor comprises preparing a semiconductor substrate having a pixel region and a peripheral circuit region. A photoelectric conversion part is formed in the pixel region of the semiconductor substrate. A plurality of interlayer dielectric layers interposed with electrically connected wires are formed on the semiconductor substrate. A conductive pad electrically connected to the wires in the peripheral circuit region is formed. A passivation layer is formed. An opening exposing the conductive pad is formed by etching the passivation layer. A bump connected to the conductive pad is formed by a plating process using the conductive pad as a seed layer.

In another exemplary embodiment, a semiconductor chip comprises a conductive pad electrically connected to a semiconductor substrate. A passivation layer has an opening exposing the conductive pad. A bump is directly connected to the conductive pad through the opening. The conductive pad and the bump are formed of the same metal.

In another exemplary embodiment, an image sensor comprises a semiconductor substrate having a pixel region and a peripheral circuit region. A photoelectric conversion part is formed in the pixel region of the semiconductor substrate. An interlayer dielectric layer covers the semiconductor substrate. A wire is disposed in the interlayer dielectric layer electrically connected to the semiconductor substrate. A conductive pad is electrically connected to the wire in the peripheral circuit region. A passivation layer includes an opening exposing the conductive pad. A bump is directly connected to the conductive pad through the opening. The conductive pad and the bump are formed of the same metal.

### BRIEF DESCRIPTION OF THE DRAWINGS

A more complete appreciation of the present disclosure will be readily obtained as the same becomes better understood by reference to the following detailed description when considered in connection with the accompanying drawings, wherein:

FIGS. 1 to 4 are cross-sectional views illustrating a method of forming an image sensor according to embodiments of the present invention.

### DETAILED DESCRIPTION OF THE EMBODIMENTS

The present invention will now be described more fully hereinafter with reference to the accompanying drawings, in which embodiments of the invention are shown. This invention, however, may be embodied in many different forms and should not be construed as limited to the embodiments set forth herein. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

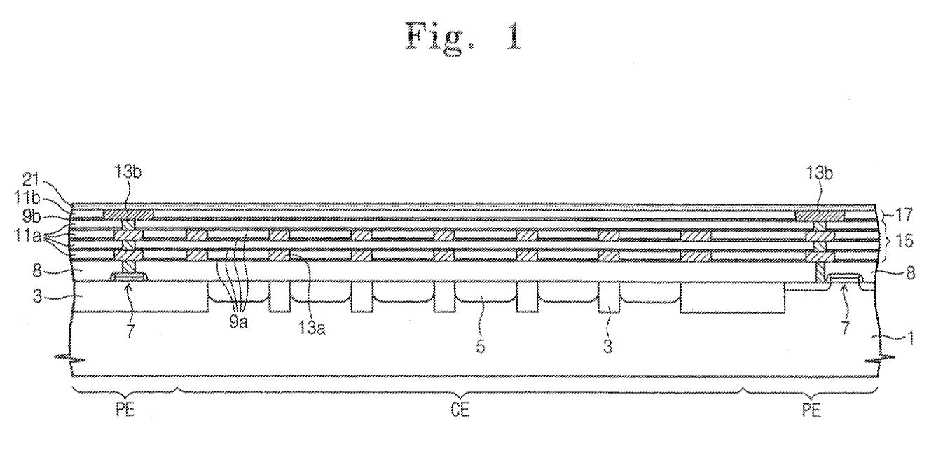

FIGS. 1 to 4 are cross-sectional views illustrating a method of forming an image sensor according to embodiments of the present invention.

Referring to FIG. 1, a device isolation layer 3 is formed on a semiconductor substrate 1 having a pixel region CE and a peripheral circuit region PE to define an active region. An ion implantation process is performed in the active region to form a photoelectric conversion part 5 such as a photodiode. If light is incident in a following device operation, an electron-hole pair is generated in the photoelectric conversion part. Transistors 7 are formed on the semiconductor substrate 1. Although not illustrated in FIG. 1, transistors are formed in the pixel region CE to sense charges generated in the photoelectric conversion part 5 at the following device operation and transmit a signal. A passivation layer 8 is formed on the semiconductor substrate 1. The passivation layer 8 is formed to protect the photoelectric conversion part 5 in the following process. A wiring layer 15 is formed on the semiconductor substrate 1. In the wiring layer 15, wires are formed to provide electric signals to the semiconductor substrate 1 or/and the transistors 7 and the wiring layer 15 includes a plurality of first etch stopping layers 9A, a plurality of first interlayer dielectric layers 11A and wires 13A penetrating the first interlayer dielectric layer 11A and the first etch stopping layer 9A. The wires 13A are electrically connected to the semiconductor substrate 1 or transistors 7. The wires 13A are formed of at least one material chosen in a group including copper, aluminum and tungsten. In the pixel region CE, since the wires 13A are formed to overlap with the device isolation layer 3, the wires 13A do not obstruct a path of incident light in the photoelectric conversion part 5.

A pad layer 17 is formed on the wiring layer 15. In the pad layer 17, a conductive pad is formed for electrical connection to the outside and the pad layer 17 includes a second etch stopping layer 9B, a second interlayer dielectric layer 11B, and a conductive pad 13B penetrating the second interlayer dielectric layer 11B and the second etch stopping layer 9B. A method of forming the pad layer 17 is as follows. Firstly, a second etch stopping layer 9B and a second interlayer dielectric layer 11B are formed on the wiring layer 15. The second interlayer dielectric layer 11B and the second etch stopping layer 9B are patterned to form a hole (not shown) exposing the wires 13A. Although not illustrated, a seed layer is formed by using a chemical vapor deposition or an atomic layer deposition and a conductive layer such as copper or gold is formed by using electroplating or electroless plating to fill the hole. And a conductive pad 13B is formed in the hole performing a chemical mechanical polishing for the conductive layer.

The etch stopping layers 9A, 9B may be formed of, for example, silicon nitride layer Si₃N₄. The interlayer dielectric layers 11A, 11B may be formed of, for example, silicon oxide layer SiO₂ or silicon oxyfluorine layer SiOF. A passivation layer 21 is formed on the pad layer 17. The passivation layer 21 may be formed of using at least one chosen in a group including silicon nitride layer, silicon oxide layer and silicon oxynitride layer, for example, a silicon nitride layer-silicon oxide layer-silicon nitride layer. The passivation layer 21 plays a role of protecting moisture from the outside.

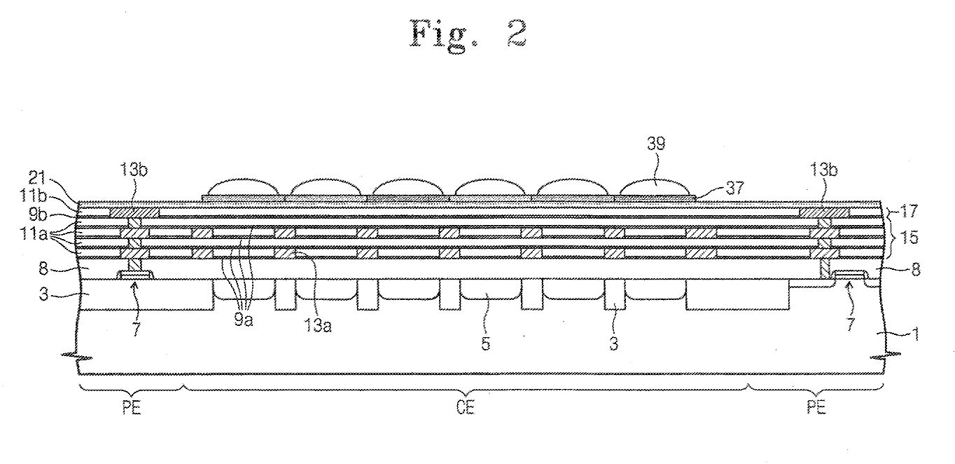

Referring to FIG. 2, a color filter layer 37 is formed on the pixel region CE overlapping with the photoelectric conversion part 5. The color filter layer 37 may be a red-green-blue RGB type color filter separating natural light into three primary colors or a complementary type color filter separating natural light into four colors, cyan, yellow, green, and magenta CYGM. A micro lens 39 is formed on the color filter layer 37. Since the conductive pad 13B is covered by the passivation layer 21, damage of the conductive pad 13B may be prevented during a process of forming the color filter layer 37 and the micro lens 39. Also, if the conductive pad 13B is formed of copper, during a process of forming the color filter layer 37 and the micro lens 39, copper is diffused by the passivation layer 21 to prevent the device from becoming polluted.

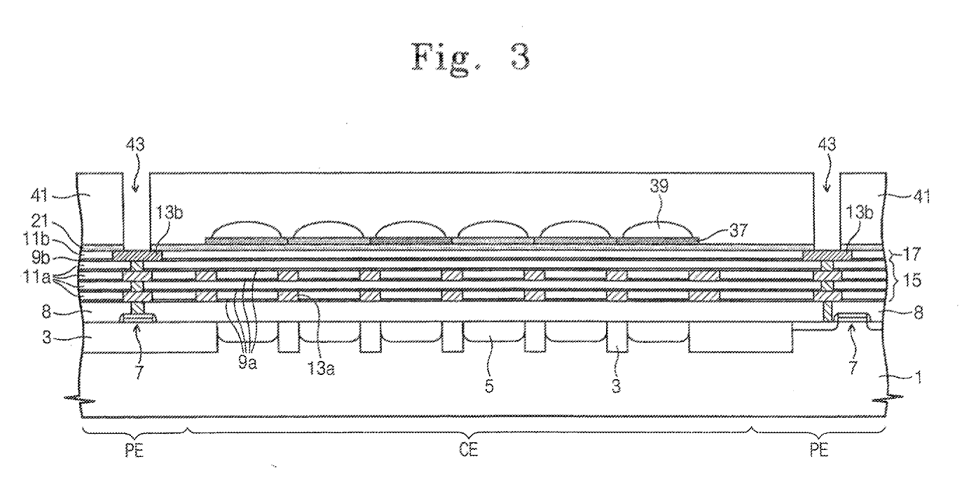

Referring to FIG. 3, after the color filter layer 37 and the micro lens 39 are formed, a mask pattern 41 having an opening 43 overlapping with the conductive pad 13B of the peripheral circuit region PE is formed. The mask pattern 41 is formed of a material having an etch selectivity with respect to the interlayer dielectric layer 11B, the micro lens 39, and the color filter layer 37. By using the mask pattern as an etch mask, the passivation layer 21 is patterned to expose the conductive pad 13B in the peripheral circuit region PE.

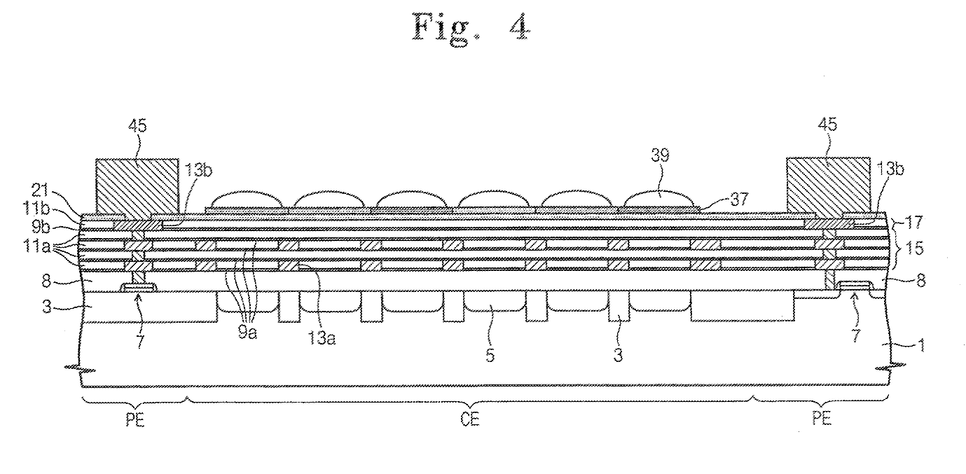

Referring to FIG. 4, the mask pattern 41 is removed. And a plating process using the conductive pad 13B as a seed layer is performed to form a bump 45 directly connected to the conductive pad 13B. The plating process may be electroplating or electroless plating. In the plating process, the bump 45 is formed of the same metal as the conductive pad 13B. That is, when the conductive pad 13B is formed of gold, the bump 45 is formed of gold. Or when the conductive pad 13B is formed of copper, the bump 45 is formed of copper.

In the plating process, since the conductive pad 13B is used as a seed layer and no separate seed layer is formed, the manufacturing process may be simplified. Also, in the manufacturing process, the copper or gold composing the bump 45 slowly grows from the center of the conductive pad 13B to the side to form an almost rectangular parallelepiped shape. Accordingly, a separate mask pattern is not necessary to define a shape of the bump 45. Accordingly, the manufacturing process may be simplified.

On the other hand, when a semiconductor device is very highly integrated, a mask pattern may be needed in order to define a shape of the bump 45.

After forming an image sensor as the above, the bump comes in contact with a circuit substrate (not shown) and a voltage is provided from the outside through the bump. From this, since an image sensor chip is connected to the circuit substrate by the bump not by a wiring, an area of a whole package is decreased by a short length of the bump and an area of light receiving part can be increased as much as an increased area.

On the other hand, a method of forming an image sensor according to the other exemplary embodiment of the present invention, is that by using the method of forming the bump as stated above, all conductive materials used as an electric coupling means, such as a wire, a conductive pad, and a bump are formed of one single material such as copper. In this case, by using the single material, compatibility of a device is increased, process load is decreased and the manufacturing process is simplified. For example, when wires are formed of two different materials, two types of deposition equipment, etch equipment, cleaning equipment, and cleaning solution are necessary. However, if a single material is used, one type of equipments and cleaning solution is necessary thereby simplifying the manufacturing process.

According to a method of forming a bump and a method of forming an image sensor according to an embodiment of the present invention, a conductive pad is used as a seed layer to form a bump by a plating process. With this, since the conductive pad is used as a seed layer, it is not necessary to form an additional aluminum pad or seed layer. Accordingly, the manufacturing process is simplified. Also, a conductive pad and a bump are formed of the same materials to simplify the manufacturing process when using a single material. Since the bump is formed by a plating process, it is possible to form a bump with a defined shape without a separate mask pattern. With this, a photolithography process and an etch process for forming a mask pattern may be omitted to simplify the manufacturing process. Also, if the conductive pad and the bump are formed of copper, the manufacturing process may be made less expensive.

What is claimed is:

1. A method of forming a bump comprising:
forming a conductive pad on a semiconductor substrate;
forming a passivation layer on the conductive pad;
forming an opening exposing the conductive pad by patterning the passivation layer;
forming a bump connected to the conductive pad by a plating process using the conductive pad as a seed layer.

2. The method of forming the bump of claim 1, wherein the conductive pad and the bump are formed of the same metal.

3. The method of forming the bump of claim 2, wherein the metal is gold or copper.

4. The method of forming the bump of claim 1, wherein the plating process is electroplating of electroless plating.

5. A method of forming an image sensor comprising:
preparing a semiconductor substrate having a pixel region and a peripheral circuit region;
forming a photoelectric conversion part in the pixel region of the semiconductor substrate;
forming a plurality of interlayer dielectric layers and interposed electrically connected wires on the semiconductor substrate;
forming a conductive pad electrically connected to the wires in the peripheral circuit region;
forming a passivation layer;
forming an opening exposing the conductive pad by etching the passivation layer; and
forming a bump connected to the conductive pad, wherein forming the bump is performed by a plating process using the conductive pad as a seed layer.

6. The method of forming the image sensor of claim 5, further comprising before forming the opening:
forming a color filter layer overlapping with the photoelectric conversion part in the pixel region; and
forming a micro lens on the color filter layer.

7. The method of forming the image sensor of claim 5, wherein the conductive pad and the bump are formed of the same metal.

8. The method of forming the image sensor of claim 7, wherein the metal is gold or copper.

9. The method of forming the image sensor of claim 5, wherein the plating process is electroplating or electroless plating.

10. A semiconductor chip comprising:
a conductive pad electrically connected to a semiconductor substrate;
a passivation layer having an opening exposing the conductive pad;
a bump directly connected to the conductive pad through the opening, wherein the conductive pad and the bump are formed of the same metal.

11. The semiconductor chip of claim 10, wherein the metal is gold or copper.

12. An image sensor comprising:
a semiconductor substrate having a pixel region and a peripheral circuit region;
a photoelectric conversion part formed in the pixel region of the semiconductor substrate;
an interlayer dielectric layer covering the semiconductor substrate;
a wire disposed in the interlayer dielectric layer and electrically connected to the semiconductor substrate;
a conductive pad electrically connected to the wire in the peripheral circuit region;
a passivation layer including an opening exposing the conductive pad; and
a bump directly connected to the conductive pad through the opening, wherein the conductive pad and the bump are formed of the same metal.

13. The image sensor of claim 12, wherein the metal is gold or copper.

14. The image sensor of claim 12, further comprising:
a color filter layer located on the passivation layer and overlapping with the photoelectric conversion part in the pixel region; and
a micro lens located on the color filter layer.
